(19) United States
(12) Patent Application Publication
(10) Pub. No.: US 2021/0066064 A1
(43) Pub. Date: Mar. 4, 2021

(54) METHODS AND APPARATUS FOR CLEANING METAL CONTACTS

(71) Applicant: APPLIED MATERIALS, INC., Santa Clara, CA (US)

(72) Inventors: He REN, San Jose, CA (US); Shi YOU, San Jose, CA (US); Hao JIANG, San Jose, CA (US); Raymond HUNG, Palo Alto, CA (US); Mehul NAIK, San Jose, CA (US); Chentsau Chris YING, Cupertino, CA (US); Mang-Mang LING, San Jose, CA (US); Lin DONG, Santa Clara, CA (US)

(21) Appl. No.: 17/004,850

(22) Filed: Aug. 27, 2020

Related U.S. Application Data
(60) Provisional application No. 62/894,372, filed on Aug. 30, 2019.

(51) Int. Cl. H01L 21/02

(52) U.S. Cl. CPC H01L 21/0206; H01L 21/0234; H01L 21/02082

(57) ABSTRACT

Methods and apparatus for cleaning a contaminated metal surface on a substrate, including: exposing a substrate including a dielectric surface and a metal surface including metal nitride residues and metal carbide residues to a process gas including an oxidizing agent to form a substrate including a dielectric surface and a metal surface including metal oxides residues; and exposing a substrate including a dielectric surface and a metal surface including metal oxides residues to a process gas including a reducing agent to form a substrate including a dielectric surface and a substantially pure metal surface.

### CROSS-REFERENCE TO RELATED APPLICATIONS

This application claims benefit of U.S. provisional patent application Ser. No. 62/894,372, filed Aug. 30, 2019, which is hereby incorporated by reference in its entirety.

### FIELD

Embodiments of the present disclosure generally relate to methods of processing substrates.

### BACKGROUND

Metals such as tungsten have been used in logic contact, middle-of-line, and metal gate fill semiconductor applications for low resistivity and conformal bulk fill characteristics. Contacts and local interconnects form the electrical pathways between the transistors and the remainder of a semiconductor circuit. Low resistivity is crucial for robust and reliable device performance. As scaling has progressed, however, interconnect dimensions have decreased to the point at which contact resistance is an obstacle to transistor performance.

While traditional metal contact formation may include an underlying metal layer, a metal liner layer, and a chemical vapor deposition (CVD) metal layer, interconnect dimensions have decreased to the point where liner usage is undesirable. The inventors have observed that liner usage may be avoided by selectively depositing a metal layer directly atop the underlying metal layer. However, the inventors have further observed that selective deposition is problematic where the underlying metal layer includes contaminants such as metal oxides, metal carbides, and metal nitrides as a result of feature formation atop the underlying metal layer. The contaminants problematically form a dense top portion of the underlying metal layer having high resistivity, while substantially pure or pure portions of the underlying metal layer having low resistivity remain out of direct contact with selectively deposited metal layers.

Further, the inventors have observed problematic incubation delay when subsequently selectively depositing a metal layer on the top surface of a contaminated underlying metal layer. The incubation delay of a CVD metal layer will vary depending on the surface film properties of the underlying metal layer. An oxide, carbide, or nitride containing film causes more delays than pure metal films.

Moreover, incubation delay can vary between the field region of a substrate and within a feature (e.g. a via or a trench) resulting in voids or large seams during a CVD metal gap fill process. The presence of such voids or large seams will problematically result in higher contact resistance and poor reliability.

As the feature size of an integrated circuit continues shrinking, especially for contact structures (e.g. a trench or via) at the 10 nm level, the contributions towards contact resistance from a contaminated underlying metal material will be significantly increased and cause high contact resistances, which will limit the device driving current and deteriorate the device performance. In addition, the incubation delay variation can cause severe gap fill problems, such as voids, resulting in poor reliability as well as high resistance.

Thus, the inventors have provided improved methods for metal contact formation.

### SUMMARY

Methods and apparatus for processing a semiconductor substrate and cleaning a contaminated metal surface are provided herein. In some embodiments, a method for cleaning a contaminated metal surface on a substrate, includes: exposing a substrate including a dielectric surface and a metal surface including metal nitride residues and metal carbide residues to a process gas including an oxidizing agent to form a substrate including a dielectric surface and a metal surface including metal oxides residues; and exposing a substrate including a dielectric surface and a metal surface including metal oxides residues to a process gas including a reducing agent to form a substrate including a dielectric surface and a substantially pure metal surface.

In some embodiments, the present disclosure includes a process chamber configured for cleaning a contaminated metal surface on a substrate. In embodiments, the process chamber is configures for exposing a substrate including a dielectric surface and a metal surface including metal nitride residues and metal carbide residues to a process gas including an oxidizing agent to form a substrate including a dielectric surface and a metal surface including metal oxides residues; and configured for exposing a substrate including a dielectric surface and a metal surface including metal oxides residues to a process gas including a reducing agent to form a substrate including a dielectric surface and a substantially pure metal surface.

In some embodiments, the present disclosure relates to a non-transitory computer readable medium having instructions stored thereon that, when executed, cause a reaction chamber to perform a method of cleaning a contaminated metal surface on a substrate, including: exposing a substrate including a dielectric surface and a metal surface including metal nitride residues and metal carbide residues to a process gas including an oxidizing agent to form a substrate including a dielectric surface and a metal surface including metal oxides residues; and exposing a substrate including a dielectric surface and a metal surface including metal oxides residues to a process gas including a reducing agent to form a substrate including a dielectric surface and a substantially pure metal surface.

In some embodiments, a method for cleaning a contaminated metal surface on a substrate, includes: exposing a substrate including a dielectric surface and a metal surface including metal oxide residues, metal nitride residues and metal carbide residues to a process gas including a chlorine gas mixed with at least one of an inert gas, nitrogen, or helium to form a substrate including a dielectric surface and a substantially pure metal surface.

In some embodiments, the present disclosure relates to a non-transitory computer readable medium having instructions stored thereon that, when executed, cause a reaction chamber to perform a method of cleaning a contaminated metal surface on a substrate, including: exposing a substrate including a dielectric surface and a metal surface including metal oxide residues, metal nitride residues and metal carbide residues to a process gas including a chlorine gas mixed with at least one of an inert gas, nitrogen, or helium to form a substrate including a dielectric surface and a substantially pure metal surface.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a process chamber suitable for cleaning a metal surface in accordance with embodiments if the present disclosure.

FIG. 2 depicts a flow chart of a method for cleaning a metal surface in accordance with some embodiments of the present disclosure.

FIGS. 3A-3C respectively depict side cross-sectional views of an interconnect structure formed in a substrate in accordance with some embodiments of the present disclosure.

FIG. 4 depicts a cluster tool suitable to perform methods for processing a substrate in accordance with some embodiments of the present disclosure.

FIG. 5 depicts a flow chart of a method for cleaning a metal surface in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Methods for forming metal contacts having one or more metal surfaces cleaned of contaminants such as metal oxides, metal nitrides, and/or metal carbides are provided herein. In embodiments, the present disclosure provides a method for cleaning a contaminated metal surface on a substrate, including: exposing a substrate including a dielectric surface and a metal surface including metal nitride residues and metal carbide residues to a process gas including an oxidizing agent to form a substrate including a dielectric surface and a metal surface including metal oxides residues; and exposing a substrate including a dielectric surface and a metal surface including metal oxides residues to a process gas including a reducing agent to form a substrate including a dielectric surface and a substantially pure metal surface. The inventive methods described herein may advantageously be used to facilitate formation of improved metal contacts, vias, and gates by removing contaminants from a metal underlayer to avoid both high contact resistance and poor gap fill. By removing contaminants of a metal underlayer surface such as metal carbides, metal nitrides, and/or metal oxides the purity of the metal underlayer can be increase leading to reduced contact resistance and increased space for subsequent metal gap fill, reducing a risk of voids or larger seams while improving device reliability.

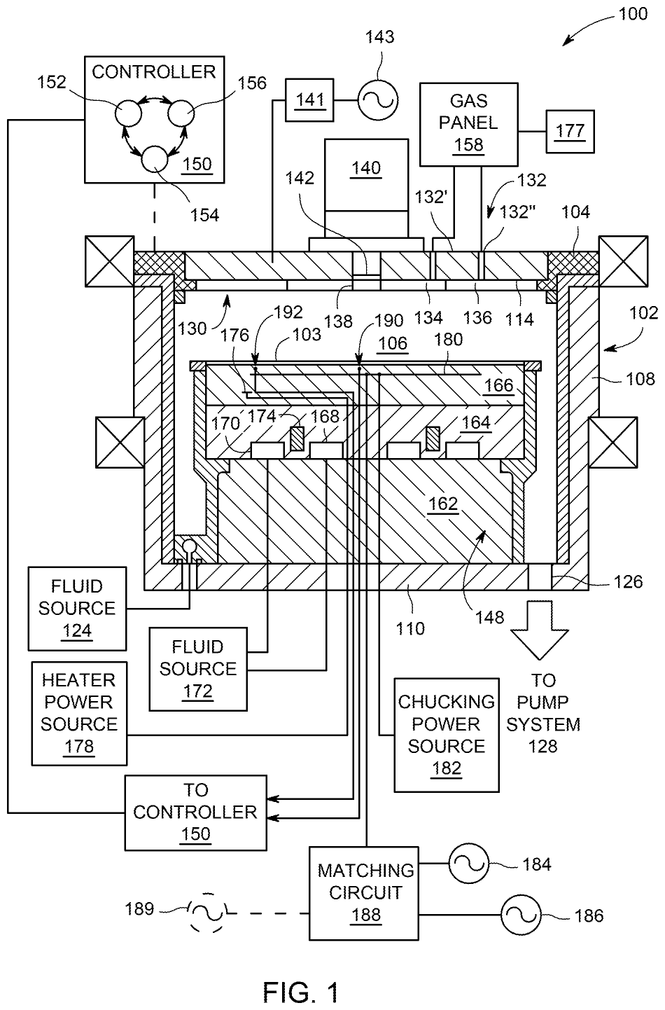

FIG. 1 is a sectional view of one example of a plasma processing chamber 100 suitable for performing a cleaning process in accordance with the present disclosure. Suitable processing chambers that may be adapted for use with the teachings disclosed herein include, for example, a SYM3® processing chamber available from Applied Materials, Inc. of Santa Clara, Calif. Other processing chambers may be adapted to benefit from one or more of the methods of the present disclosure.

The processing chamber 100 includes a chamber body 102 and a lid 104 which enclose an interior volume 106. The chamber body 102 is typically fabricated from aluminum, stainless steel or other suitable material. The chamber body 102 generally includes sidewalls 108 and a bottom 110. A substrate support pedestal access port (not shown) is generally defined in a sidewall 108 and a selectively sealed by a slit valve to facilitate entry and egress of a substrate 103 from the processing chamber 100. An exhaust port 126 is defined in the chamber body 102 and couples the interior volume 106 to a vacuum pump system 128. The vacuum pump system 128 generally includes one or more pumps and throttle valves utilized to evacuate and regulate the pressure of the interior volume 106 of the processing chamber 100. In embodiments, the vacuum pump system 128 maintains the pressure inside the interior volume 106 at operating pressures typically between about 1 mTorr to about 500 mTorr, between about 5 mTorr to about 100 mTorr, or between about 5 mTorr to 50 mTorr depending upon process needs.

In embodiments, the lid 104 is sealingly supported on the sidewall 108 of the chamber body 102. The lid 104 may be opened to allow excess to the interior volume 106 of the processing chamber 100. The lid 104 includes a window 142 that facilitates optical process monitoring. In one embodiment, the window 142 is comprised of quartz or other suitable material that is transmissive to a signal utilized by an optical monitoring system 140 mounted outside the processing chamber 100.

The optical monitoring system 140 is positioned to view at least one of the interior volume 106 of the chamber body 102 and/or the substrate 103 positioned on a substrate support pedestal assembly 148 through the window 142. In one embodiment, the optical monitoring system 140 is coupled to the lid 104 and facilitates an integrated deposition process that uses optical metrology to provide information that enables process adjustment to compensate for incoming substrate pattern feature inconsistencies (such as thickness, and the like), provide process state monitoring (such as plasma monitoring, temperature monitoring, and the like) as needed. One optical monitoring system that may be adapted to benefit from the invention is the EyeD® full-spectrum, interferometric metrology module, available from Applied Materials, Inc., of Santa Clara, Calif.

In embodiments, a gas panel 158 is coupled to the processing chamber 100 to provide process and/or cleaning gases to the interior volume 106. In the example depicted in FIG. 1, inlet ports 132′, 132″ are provided in the lid 104 to allow gases to be delivered from the gas panel 158 to the interior volume 106 of the processing chamber 100. In embodiments, the gas panel 158 is adapted to provide oxygen and inert gas such as argon, or oxygen and helium process gas or gas mixture through the inlet ports 132′, 132″ and into the interior volume 106 of the processing chamber 100. In one embodiment, the process gas provided from the gas panel 158 includes at least a process gas including an oxidizing agent such as oxygen gas. In embodiments, the process gas including an oxidizing agent may further comprise an inert gas such as argon or helium. In some embodiments, the process gas includes a reducing agent such as hydrogen, and may be mixed with an inert gas such as argon, or other gases such as nitrogen or helium. In some embodiments, a chlorine gas may be provided alone, or in combination with at least one of nitrogen, helium an inert gas such as argon. Non-limiting examples of oxygen containing gas includes one or more of O₂, CO₂, N₂O, NO₂, O₃, H₂O, and the like. Non-limiting examples of nitrogen containing gas includes N2, NH3, and the like. Non-limiting examples of chlorine containing gas includes HCl, Cl₂, CCl₄, and the like. In embodiments, a showerhead assembly 130 is coupled to an interior surface 114 of the lid 104. The showerhead assembly 130 includes a plurality of apertures that allow the gases flowing through the showerhead assembly 130 from the inlet ports 132′, 132″ into the interior volume 106 of the processing chamber 100 in a predefined distribution across the surface of the substrate 103 being processed in the processing chamber 100.

In some embodiments, the processing chamber 100 may utilize capacitively coupled RF energy for plasma processing, or in some embodiments, processing chamber 100 may use inductively coupled RF energy for plasma processing. In some embodiments, a remote plasma source 177 may be optionally coupled to the gas panel 158 to facilitate dissociating gas mixture from a remote plasma prior to entering into the interior volume 106 for processing. A RF source power 143 is coupled through a matching network 141 to the showerhead assembly 130. The RF source power 143 typically is capable of producing up to about 5000 W for example between about 200 W to about 5000 W, or between 1000 W to 3000 W, or about 1500 W and optionally at a tunable frequency in a range from about 50 kHz to about 200 MHz.

The showerhead assembly 130 additionally includes a region transmissive to an optical metrology signal. The optically transmissive region or passage 138 is suitable for allowing the optical monitoring system 140 to view the interior volume 106 and/or the substrate 103 positioned on the substrate support pedestal assembly 148. The passage 138 may be a material, an aperture or plurality of apertures formed or disposed in the showerhead assembly 130 that is substantially transmissive to the wavelengths of energy generated by, and reflected back to, the optical monitoring system 140. In one embodiment, the passage 138 includes a window 142 to prevent gas leakage through the passage 138. The window 142 may be a sapphire plate, quartz plate or other suitable material. The window 142 may alternatively be disposed in the lid 104.

In one embodiment, the showerhead assembly 130 is configured with a plurality of zones that allow for separate control of gas flowing into the interior volume 106 of the processing chamber 100. In the example illustrated in FIG. 1, the showerhead assembly 130 as an inner zone 134 and an outer zone 136 that are separately coupled to the gas panel 158 through separate inlet ports 132′, 132″.

The substrate support pedestal assembly 148 is disposed in the interior volume 106 of the processing chamber 100 below the showerhead assembly 130. The substrate support pedestal assembly 148 holds the substrate 103 during processing. The substrate support pedestal assembly 148 generally includes a plurality of lift pins (not shown) disposed therethrough that are configured to lift the substrate 103 from the substrate support pedestal assembly 148 and facilitate exchange of the substrate 103 with a robot (not shown) in a conventional manner. An inner liner may closely circumscribe the periphery of the substrate support pedestal assembly 148. In some embodiments, the inner liner, or portions thereof, may be cooled, for example, by having channels formed therein for flowing therethrough a heat transfer fluid provided by a fluid source 124.

In one embodiment, the substrate support pedestal assembly 148 includes a mounting plate 162, a base 164 and an electrostatic chuck 166. The mounting plate 162 is coupled to the bottom 110 of the chamber body 102 includes passages for routing utilities, such as fluids, power lines and sensor leads, among others, to the base 164 and the electrostatic chuck 166. The electrostatic chuck 166 comprises at least one clamping electrode 180 for retaining the substrate 103 below showerhead assembly 130. The electrostatic chuck 166 is driven by a chucking power source 182 to develop an electrostatic force that holds the substrate 103 to the chuck surface, as is conventionally known. Alternatively, the substrate 103 may be retained to the substrate support pedestal assembly 148 by clamping, vacuum or gravity.

At least one of the base 164 or electrostatic chuck 166 may include at least one optional embedded heater 176, at least one optional embedded isolator 174 and a plurality of conduits 168, 170 to control the lateral temperature profile of the substrate support pedestal assembly 148. The conduits 168, 170 are fluidly coupled to a fluid source 172 that circulates a temperature regulating fluid therethrough. The heater 176 is regulated by a power source 178. The conduits 168, 170 and heater 176 are utilized to control the temperature of the base 164, thereby heating and/or cooling the electrostatic chuck 166 and ultimately, the temperature profile of the substrate 103 disposed thereon. The temperature of the electrostatic chuck 166 and the base 164 may be monitored using a plurality of temperature sensors 190, 192. The electrostatic chuck 166 may further comprise a plurality of gas passages (not shown), such as grooves, that are formed in a substrate support pedestal supporting surface of the electrostatic chuck 166 and fluidly coupled to a source of a heat transfer (or backside) gas, such as He. In operation, the backside gas is provided at controlled pressure into the gas passages to enhance the heat transfer between the electrostatic chuck 166 and the substrate 103. In embodiments, the temperature of the substrate may be maintained at 20 degrees Celsius to 450 degrees Celsius, such as 100 to 300 degrees Celsius, or 150 to 250 degrees Celsius.

In some embodiments, the substrate support pedestal assembly 148 is configured as a cathode and includes an electrode 180 that is coupled to a plurality of RF bias power sources 184, 186. The RF bias power sources 184, 186 are coupled between the electrode 180 disposed in the substrate support pedestal assembly 148 and another electrode, such as the showerhead assembly 130 or ceiling (lid 104) of the chamber body 102. The RF bias power (e.g., plasma bias power) excites and sustains a plasma discharge formed from the gases disposed in the processing region of the chamber body 102.

Still referring to FIG. 1, in some embodiments the dual RF bias power sources 184, 186 are coupled to the electrode 180 disposed in the substrate support pedestal assembly 148 through a matching circuit 188. The signal generated by the RF bias power sources 184, 186 is delivered through matching circuit 188 to the substrate support pedestal assembly 148 through a single feed to ionize the gas mixture provided in the plasma processing chamber 100, thus providing ion energy necessary for performing an etch deposition or other plasma enhanced process. The RF bias power source 184, 186 are generally capable of producing an RF signal having a frequency of from about 50 kHz to about 200 MHz and a power between about 0 watts (W) and about 500 W, 1 W to about 100 W, or about 1 W to about 30 W. An additional bias power 189 may be coupled to the electrode 180 to control the characteristics of the plasma.

During operation, the substrate 103 is disposed on the substrate support pedestal assembly 148 in the plasma processing chamber 100. A process gas and/or gas mixture is introduced into the chamber body 102 through the showerhead assembly 130 from the gas panel 158. The vacuum pump system 128 maintains the pressure inside the chamber body 102 while removing deposition by-products.

A controller 150 is coupled to the processing chamber 100 to control operation of the processing chamber 100, such as to perform any of the methods or disclosed herein or portions thereof. The controller 150 includes a central processing unit (CPU) 152, a memory 154, and a support circuit 156 utilized to control the process sequence and regulate the gas flows from the gas panel 158. The CPU 152 may be any form of general purpose computer processor that may be used in an industrial setting. The software routines can be stored in the memory 154, such as random access memory, read only memory, floppy, or hard disk drive, or other form of digital storage. The support circuit 156 is conventionally coupled to the CPU 152 and may include cache, clock circuits, input/output systems, power supplies, and the like. Bi-directional communications between the controller 150 and the various components of the processing chamber 100 are handled through numerous signal cables.

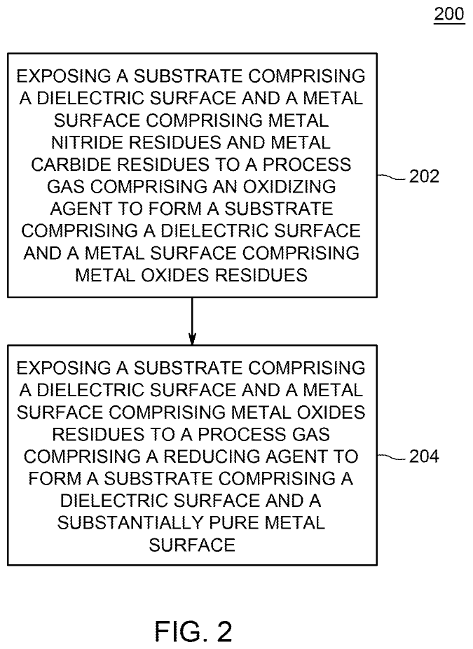

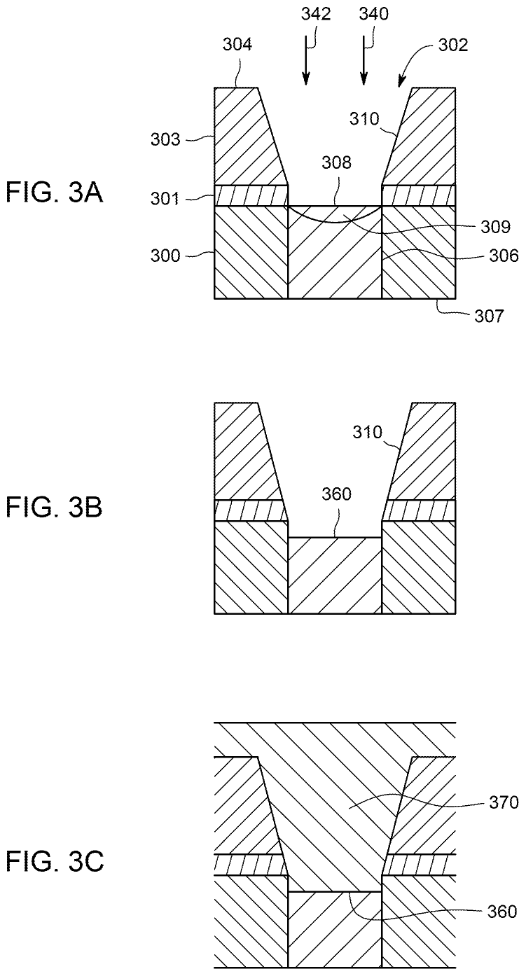

FIG. 2 depicts a flow chart of a method 200 for cleaning a contaminated metal surface on a substrate 300 in accordance with some embodiments of the present disclosure. Although the method 200 is described below with respect to the stages of filling a high aspect ratio feature 206 as depicted in FIGS. 3A-3C, the disclosure provided herein can be used to deposit a metal material as a sheet or blanket upon or atop a substrate, e.g., without having features such as a high aspect ratio feature. In addition, the disclosure provided herein can also be used to fill features having other aspect ratios other than a high aspect ratio. In some embodiments, metal material may be formed as a sheet or blanket on a substrate and subjected to additional process flows such as selectively filling, etching, and/or capping. The method 200 may be performed in any suitable process chamber such as a processing chamber 100 described above and depicted in FIG. 1.

In embodiments, the method 200 of FIG. 2 begins at 202 by exposing a substrate including a dielectric surface and a metal surface including metal nitride residues and metal carbide residues to a process gas including an oxidizing agent to form a substrate including a dielectric surface and a metal surface including metal oxides residues. Referring to FIG. 3A, a substrate 300 may be provided to a processing chamber 100. In embodiments, the substrate 300 includes a high aspect ratio opening such as opening 302 formed in a first surface 304 of the substrate 300 and extending into the substrate 300 towards an opposing second surface 307 of the substrate 300. The substrate 300 may be any suitable substrate including, but not limited to a substrate having a high aspect ratio opening formed thereon. For example, the substrate 300 may comprise one or more of silicon (Si), (SiO₂), (SiN), or other dielectric materials.

In embodiments, the substrate 300 may comprise an additional layer of dielectric material such as second dielectric layer 301 directly atop substrate 300 or others, such as a third dielectric layer 303 directly atop second dielectric layer 301. In addition, the substrate 300 may optionally include additional layers of materials or may have one or more completed or partially completed structures formed therein or thereon. In embodiments, the second dielectric layer 301 may comprise one or more of silicon (Si), silicon oxide (SiO₂), silicon nitride (SiN), or other dielectric materials. In embodiments, second dielectric layer 301 may comprise silicon nitride (SiN). In embodiments, the third dielectric layer 303 may comprise one or more of silicon (Si), silicon oxide (SiO₂), silicon nitride (SiN), or other dielectric materials.

In some embodiments, the opening 302 may be any opening having a high aspect ratio, such as used to form a via, trench, dual damascene structure, or the like. In some embodiments, the opening 302 may have a height to width aspect ratio of at least about 5:1 (e.g., a high aspect ratio). For example, in some embodiments, the aspect ratio may be about 10:1 or greater, such as about 15:1, or more. The opening 302 may be formed by etching the substrate using any suitable etch process. The opening 302 includes a bottom surface 308 and dielectric sidewalls 310 as shown. In embodiments, a device 306, such as a logic device or the like, or a portion of a device 306 requiring electrical connectivity, such as a gate, a contact pad, a conductive via, or the like, may be disposed in the bottom surface 308 and aligned with the opening 302.

In embodiments, the bottom surface 308 is a metal surface 309 including metal such as tungsten, cobalt, ruthenium, molybdenum, or combinations thereof. The inventors have found that by forming the opening 302, contaminants and/or reaction byproducts become embedded in metal surface 309. Metal surface 309 as a result of contamination from metal oxides, metal nitrides, and metal carbides may form a dense metal layer not suitable for selective metal deposition. Non-limiting examples of contaminants include metal oxides, metal nitrides, and metal carbides. The inventors have observed that reacting the contaminants into metal oxides, followed by reduction to pure metal improves selective metal fill of opening 302.

At 202, embodiments of the present disclosure include exposing a substrate 300 including a dielectric surface 310 and a metal surface 309 including metal nitride residues and metal carbide residues to a process gas including an oxidizing agent performed in a process chamber at a temperature of 20 degrees Celsius to 450 degrees Celsius. In some embodiments, exposing a substrate 300 including a dielectric surface 310 and a metal surface 309 including metal nitride residues and metal carbide residues to a process gas including an oxidizing agent may be performed in a process chamber at a temperature of 100 degrees Celsius to 300 degrees Celsius, or 150 degrees Celsius to 250 degrees Celsius.

At 202, embodiments of the present disclosure include exposing a substrate 300 including a dielectric surface 310 and a metal surface 309 including metal nitride residues and metal carbide residues to a process gas including an oxidizing agent performed in a process chamber at a pressure between about 1 mTorr to 500 mTorr, between about 5 mTorr to 100 mTorr, or between about 5 mTorr to 50 mTorr.

At 202, embodiments of the present disclosure include exposing a substrate including a dielectric surface and a metal surface including metal nitride residues and metal carbide residues to a process gas including an oxidizing agent is performed in a process chamber including a plasma source power at 1 W to 5000 W. For example, in embodiments, exposing a substrate 300 including a dielectric surface 310 and a metal surface 309 including metal nitride residues and metal carbide residues to a process gas including an oxidizing agent may be performed in a process chamber providing a plasma source power of 500 W to 5000 W, 1000 W to 3000 W, or about 1500 W.

At 202, embodiments of the present disclosure include exposing a substrate including a dielectric surface and a metal surface including metal nitride residues and metal carbide residues to a process gas including an oxidizing agent in a process chamber including a plasma bias power at 1 W to 500 W (e.g., using RF bias power sources 184, 186). For examples, embodiments, include exposing a substrate 300 including a dielectric surface 310 and a metal surface 309 including metal nitride residues and metal carbide residues to a process gas including an oxidizing agent may be performed in a process chamber providing a plasma bias power of 0 to 500 W, 1 W to 500 W, 0 to 100 W, or 1 to 100 W, such as about 75 W.

At 202, embodiments of the present disclosure include exposing a substrate 300 including a dielectric surface 310 and a metal surface 309 including metal nitride residues and metal carbide residues to a process gas including an oxidizing agent may be performed in a process chamber, wherein the process gas includes one or more mixtures of oxygen and an inert gas such as argon, or mixtures of oxygen and helium. Non-limiting examples of suitable process gas for exposing a substrate 300 including a dielectric surface 310 and a metal surface 309 including metal nitride residues and metal carbide residues includes first process gas 340 including a process gas including an oxidizing agent including a mixture of oxygen and argon, or a mixture of oxygen and helium.

In embodiments, exposing a substrate 300 including a dielectric surface 310 and a metal surface 309 including metal nitride residues and metal carbide residues coverts the metal nitride residues and metal carbide residues into metal oxides which remain available for reduction. In embodiments, metal oxide contaminants included in metal surface 309 prior to process sequence 202, also remain available for reduction as described herein.

Referring now to FIG. 2, method 200 includes, subsequent to process sequence 202, process sequence 204 including exposing a substrate 300 including a dielectric surface 310 and a metal surface 309 including metal oxides residues to a second process gas 342 such as process gas including a reducing agent to form a substrate 300 including a dielectric surface 310 and a substantially pure or pure metal surface 360 (as shown in FIG. 3B).

At 204, embodiments, of the present disclosure include exposing a substrate 300 including a dielectric surface 310 and a metal surface 309 including metal oxides residues to a second process gas 342 such as process gas including a reducing agent may be performed in a process chamber at a temperature of 20 degrees Celsius to 450 degrees Celsius, 100 degrees Celsius to 300 degrees Celsius, or 150 degrees Celsius to 250 degrees Celsius.

At 204, embodiments of the present disclosure include exposing a substrate 300 including a dielectric surface 310 and a metal surface 309 including metal oxides residues to a second process gas 342 such as process gas including a reducing agent may be performed in a process chamber at a pressure of 1 mTorr to 500 mTorr, between about 5 mTorr to 100 mTorr, or between about 5 to 50 mTorr.

At 204, embodiments of the present disclosure include exposing a substrate 300 including a dielectric surface 310 and a metal surface 309 including metal oxides residues to a second process gas 342 such as process gas including a reducing agent may be performed in a process chamber providing a plasma source power of 500 to 5000 W, 500 W to 2000 W, 500 W to 1000 W or about 900 W.

At 204, embodiments of the present disclosure include exposing a substrate 300 including a dielectric surface 310 and a metal surface 309 including metal oxides residues to a second process gas 342 such as process gas including a reducing agent may be performed in a process chamber providing a plasma bias power of 0 to 500 W, 1 to 500 W, 0 to 100 W, or 1 to 100 W, such as 75 W.

At 204, embodiments of the present disclosure include exposing a substrate 300 including a dielectric surface 310 and a metal surface 309 including metal oxides residues to a second process gas 342 such as process gas including a reducing agent may be performed in a process chamber including process gas including a reducing agent may be performed in a process chamber wherein the process gas includes one or more mixtures of hydrogen and an inert gas such as argon, or mixtures of hydrogen and helium, or mixtures of hydrogen and nitrogen containing gas. Non-limiting examples of suitable process gas for exposing a substrate 300 including a dielectric surface 310 and a metal surface 309 including metal oxide residues includes process gas including a reducing agent wherein the reducing agent includes a mixture of hydrogen and argon, a mixture of hydrogen and helium, or a mixture of hydrogen and nitrogen.

Upon reduction of metal oxide contaminants to substantially pure or pure metal, substantially pure or pure metal surface 360 is suitable for additional processing such as subsequent selective metal deposition directly thereon. As shown in FIG. 3C, further processing of the substrate cleaned in accordance with the present disclosure includes selectively depositing a metal 370 atop a substantially pure or pure metal surface 360 described above. For example, wherein substantially pure or pure metal surface 360 comprises tungsten, additional tungsten may be selectively deposited directly atop the substantially pure or pure metal surface 360 filling the feature as shown in FIG. 3C. In embodiments, the substrate 300 may be moved without vacuum break to an additional chamber suitable for selective metal deposition. One non-limiting example of a chamber suitable for selective metal deposition includes a VOLTA® brand processing chamber available from Applied Materials, Inc., of Santa Clara, Calif. In embodiments, tungsten, cobalt, ruthenium, and molybdenum are metals suitable for deposition atop substantially pure or pure metal surface 360.

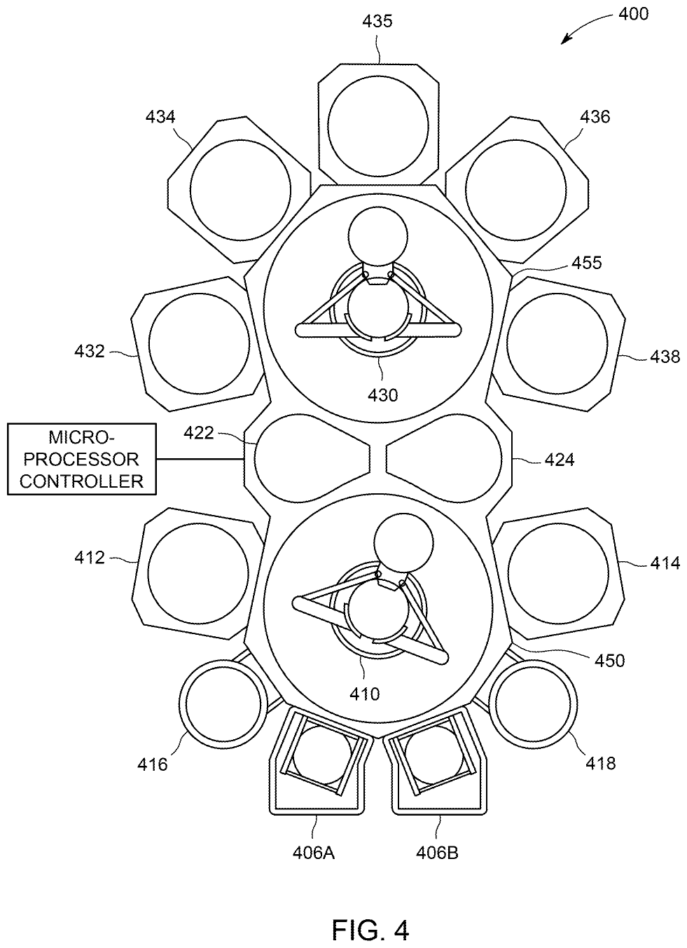

Referring now to FIG. 4, the methods described herein may be performed in individual process chambers that may be provided in a standalone configuration or as part of one or more cluster tools, for example, an integrated tool 400 (i.e., cluster tool) described below with respect to FIG. 4. In embodiments, a cluster tool is configured for performing the methods for processing a substrate as described herein including: exposing a substrate including a dielectric surface and a metal surface including metal nitride residues and metal carbide residues to a process gas including an oxidizing agent to form a substrate including a dielectric surface and a metal surface including metal oxides residues; and exposing a substrate including a dielectric surface and a metal surface including metal oxides residues to a process gas including a reducing agent to form a substrate including a dielectric surface and a substantially pure metal surface. In embodiments, the cluster tool may be configured to move a substrate including substantially pure or pure metal surface 360 to another process chamber suitable for performing selective deposition of additional metal atop the substantially pure or pure metal surface 360. Non-limiting examples of an additional chamber for selective metal deposition includes the VOLTA® brand processing chamber available from Applied Materials, Inc., of Santa Clara, Calif. Examples of the integrated tool 400 include the CENTURA® and ENDURA® integrated tools, available from Applied Materials, Inc., of Santa Clara, Calif. However, the methods described herein may be practiced using other cluster tools having suitable process chambers coupled thereto, or in other suitable process chambers. For example, in some embodiments the inventive methods discussed above may advantageously be performed in an integrated tool such that there are limited or no vacuum breaks while processing.

In embodiments, the integrated tool 400 can include two load lock chambers 406A, 406B for transferring of substrates into and out of the integrated tool 400. Typically, since the integrated tool 400 is under vacuum, the load lock chambers 406A, 406B may “pump down” the substrates introduced into the integrated tool 400. A first robot 410 may transfer the substrates between the load lock chambers 406A, 406B, and a first set of one or more substrate processing chambers 412, 414, 416, 418 (four are shown) coupled to a first central transfer chamber 450. Each substrate processing chamber 412, 414, 416, 418, can be outfitted to perform a number of substrate processing operations. In some embodiments, the first set of one or more substrate processing chambers 412, 414, 416, 418 may include any combination of PVD, ALD, CVD, etch, or degas chambers. For example, in some embodiments, the processing chambers 412, and 414 include a process chamber such as shown in FIG. 1, configured to expose a substrate including a dielectric surface and a metal surface including metal nitride residues and metal carbide residues to a process gas including an oxidizing agent to form a substrate including a dielectric surface and a metal surface including metal oxides residues; and further configured for expose a substrate including a dielectric surface and a metal surface including metal oxides residues to a process gas including a reducing agent to form a substrate including a dielectric surface and a substantially pure metal surface.

In some embodiments, the first robot 410 can also transfer substrates to/from two intermediate transfer chambers 422, 424. The intermediate transfer chambers 422, 424 can be used to maintain ultrahigh vacuum conditions while allowing substrates to be transferred within the integrated tool 400. A second robot 430 can transfer the substrates between the intermediate transfer chambers 422, 424 and a second set of one or more substrate processing chambers 432, 434, 435, 436, 438 coupled to a second central transfer chamber 455. The substrate processing chambers 432, 434, 435, 436, 438 can be outfitted to perform a variety of substrate processing operations including the method 200 described above in addition to, physical vapor deposition processes (PVD), chemical vapor deposition (CVD), selective metal deposition, etching, orientation and other substrate processes. Any of the substrate processing chambers 412, 414, 416, 418, 432, 434, 435, 436, 438 may be removed from the integrated tool 400 if not necessary for a particular process to be performed by the integrated tool 400.

In some embodiments, the integrated tool 400 includes a process chamber configured for cleaning a contaminated metal surface on a substrate, wherein the method comprises: exposing a substrate including a dielectric surface and a metal surface including metal nitride residues and metal carbide residues to a process gas including an oxidizing agent to form a substrate including a dielectric surface and a metal surface including metal oxides residues; and exposing a substrate including a dielectric surface and a metal surface including metal oxides residues to a process gas including a reducing agent to form a substrate including a dielectric surface and a substantially pure metal surface.

In some embodiments, a substrate processing system, includes: a process chamber configured for exposing a substrate including a dielectric surface and a metal surface including metal nitride residues and metal carbide residues to a process gas including an oxidizing agent to form a substrate including a dielectric surface and a metal surface including metal oxides residues, wherein the process chamber is also configured for exposing a substrate including a dielectric surface and a metal surface including metal oxides residues to a process gas including a reducing agent to form a substrate including a dielectric surface and a substantially pure metal surface. In some embodiments, the substrate processing system further includes a vacuum substrate transfer chamber, wherein the process chamber is coupled to the vacuum substrate transfer chamber; and a selective metal deposition chamber coupled to the vacuum substrate transfer chamber, wherein the substrate processing system is configured to move the substrate from the process chamber to the selective metal deposition chamber under vacuum.

In some embodiments, the present disclosure relates to a non-transitory computer readable medium having instructions stored thereon that, when executed, cause a reaction chamber to perform a method of cleaning a contaminated metal surface on a substrate, including: exposing a substrate including a dielectric surface and a metal surface including metal nitride residues and metal carbide residues to a process gas including an oxidizing agent to form a substrate including a dielectric surface and a metal surface including metal oxides residues; and exposing a substrate including a dielectric surface and a metal surface including metal oxides residues to a process gas including a reducing agent to form a substrate including a dielectric surface and a substantially pure metal surface.

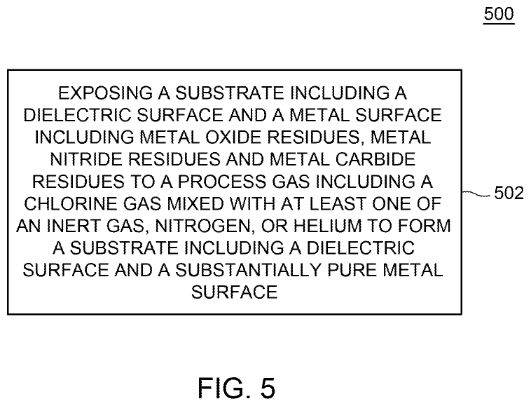

Referring now to FIG. 5, in some embodiments, a method for cleaning a contaminated metal surface on a substrate, includes at process sequence 502 exposing a substrate including a dielectric surface and a metal surface including metal oxide residues, metal nitride residues and metal carbide residues to a process gas including a chlorine gas mixed with at least one of an inert gas, nitrogen, or helium to form a substrate including a dielectric surface and a substantially pure metal surface. In some embodiments, exposing a substrate is performed in a process chamber at a temperature of 20 degrees Celsius to 450 degrees Celsius; a pressure of 1 mTorr to 500 mTorr; a plasma source power at 200 to 5000 W; and a plasma bias power at 0 to 500 W, or greater than 0 and up to about 500 W. In embodiments, the chlorine gas includes nitrogen, hydrogen, or helium.

In some embodiments, the present disclosure relates to a non-transitory computer readable medium having instructions stored thereon that, when executed, cause a reaction chamber to perform a method of cleaning a contaminated metal surface on a substrate, including: exposing a substrate including a dielectric surface and a metal surface including metal oxide residues, metal nitride residues and metal carbide residues to a process gas including a chlorine gas mixed with at least one of an inert gas, nitrogen, or helium to form a substrate including a dielectric surface and a substantially pure metal surface.

In some embodiments, the present disclosure relates to a method for cleaning a contaminated metal surface on a substrate, including: exposing a substrate comprising a dielectric surface and a tungsten surface including metal nitride residues and metal carbide residues to a process gas comprising an oxidizing agent to form a substrate comprising a dielectric surface and a tungsten surface comprising metal oxides residues; and exposing a substrate comprising a dielectric surface and a tungsten surface comprising metal oxides residues to a process gas comprising a reducing agent to form a substrate comprising a dielectric surface and a substantially pure tungsten surface. In some embodiments, exposing a substrate comprising a dielectric surface and a tungsten surface comprising metal nitride residues and metal carbide residues to a process gas comprising an oxidizing agent is performed in a process chamber: at a temperature of 20 degrees Celsius to 400 degrees Celsius; at a pressure of 1 mTorr to 500 mTorr; including a plasma source power at 1 to 5000 W, and including a plasma bias power at 1 to 500 W. In embodiments, the process gas includes an oxidizing agent including a mixture of oxygen and argon, or a mixture of oxygen and helium. In some embodiments, exposing a substrate comprising a dielectric surface and a tungsten surface including metal oxides residues to a process gas including a reducing agent is performed in a process chamber at a temperature of 20 degrees Celsius to 400 degrees Celsius; a pressure of 1 mTorr to 500 mTorr; a plasma source power at 1 to 5000 W; and a plasma bias power at 1 to 500 W. In embodiments, the reducing agent is a mixture of hydrogen and argon, hydrogen and nitrogen or hydrogen and helium.

While the foregoing is directed to embodiments of the present disclosure, other and further embodiments of the disclosure may be devised without departing from the basic scope thereof.

1. A method for cleaning a contaminated metal surface on a substrate, comprising:
exposing a substrate comprising a dielectric surface and a metal surface comprising metal nitride residues and metal carbide residues to a process gas comprising an oxidizing agent to form a substrate comprising a dielectric surface and a metal surface comprising metal oxides residues; and
exposing the substrate comprising a dielectric surface and a metal surface comprising metal oxides residues to a process gas comprising a reducing agent to form a substrate comprising a dielectric surface and a substantially pure metal surface.

2. The method of claim 1, wherein the metal surface comprises tungsten, cobalt, ruthenium, molybdenum, or combinations thereof.

3. The method of claim 1, wherein exposing a substrate comprising a dielectric surface and a metal surface comprising metal nitride residues and metal carbide residues to a process gas comprising an oxidizing agent is performed in a process chamber at a temperature of 20 degrees Celsius to 400 degrees Celsius.

4. The method of claim 1, wherein exposing a substrate comprising a dielectric surface and a metal surface comprising metal nitride residues and metal carbide residues to a process gas comprising an oxidizing agent is performed in a process chamber at a pressure of 1 mTorr to 500 mTorr.

5. The method of claim 1, wherein exposing a substrate comprising a dielectric surface and a metal surface comprising metal nitride residues and metal carbide residues to a process gas comprising an oxidizing agent is performed in a process chamber comprising a plasma source power at 1 to 5000 W.

6. The method of claim 1, wherein exposing a substrate comprising a dielectric surface and a metal surface comprising metal nitride residues and metal carbide residues to a process gas comprising an oxidizing agent is performed in a process chamber comprising a plasma bias power at 1 to 500 W.

7. The method of claim 1, wherein the process gas comprising an oxidizing agent comprises a mixture of oxygen and argon, or a mixture of oxygen and helium.

8. The method of claim 1, wherein exposing a substrate comprising a dielectric surface and a metal surface comprising metal oxides residues to a process gas comprising a reducing agent is performed in a process chamber at a temperature of 20 degrees Celsius to 400 degrees Celsius.

9. The method of claim 1, wherein exposing a substrate comprising a dielectric surface and a metal surface comprising metal oxides residues to a process gas comprising a reducing agent is performed in a process chamber at a pressure of 1 mTorr to 500 mTorr.

10. The method of claim 1, wherein exposing a substrate comprising a dielectric surface and a metal surface comprising metal oxides residues to a process gas comprising a reducing agent is performed in a process chamber comprising a plasma source power at 1 to 5000 W.

11. The method of claim 1, wherein exposing a substrate comprising a dielectric surface and a metal surface comprising metal oxides residues to a process gas comprising a reducing agent is performed in a process chamber comprising a plasma bias power at 1 to 500 W.

12. The method of claim 1, wherein the reducing agent is a mixture of hydrogen and argon, hydrogen and nitrogen or hydrogen and helium.

13. A method for cleaning a contaminated metal surface on a substrate, comprising:
exposing a substrate comprising a dielectric surface and a metal surface comprising metal nitride residues and metal carbide residues to a process gas comprising an oxidizing agent to form a substrate comprising a dielectric surface and a metal surface comprising metal oxides residues, wherein the process gas comprising an oxidizing agent comprises a mixture of oxygen and argon, or a mixture of oxygen and helium; and
exposing the substrate comprising a dielectric surface and a metal surface comprising metal oxides residues to a process gas comprising a reducing agent to form a substrate comprising a dielectric surface and a substantially pure metal surface, wherein the reducing agent is a mixture of hydrogen and argon, hydrogen and nitrogen or hydrogen and helium.

14. The method of claim 13, wherein the metal surface comprises tungsten, cobalt, ruthenium, molybdenum, or combinations thereof.

15. A non-transitory computer readable medium having instructions stored thereon that, when executed, cause a reaction chamber to perform a method of cleaning a contaminated metal surface on a substrate, the method comprising:
exposing a substrate comprising a dielectric surface and a metal surface comprising metal nitride residues and metal carbide residues to a process gas comprising an oxidizing agent to form a substrate comprising a dielectric surface and a metal surface comprising metal oxides residues; and
exposing the substrate comprising a dielectric surface and a metal surface comprising metal oxides residues to a process gas comprising a reducing agent to form a substrate comprising a dielectric surface and a substantially pure metal surface.

16. The non-transitory computer readable medium of claim 15, wherein the method further comprises:
exposing the substrate comprising a dielectric surface and a metal surface comprising metal nitride residues and metal carbide residues to the process gas comprising an oxidizing agent in a process chamber having a temperature of 20 degrees Celsius to 400 degrees Celsius and a pressure of 1 mTorr to 500 mTorr.

17. The non-transitory computer readable medium of claim 15, wherein the method further comprises:
exposing the substrate comprising a dielectric surface and a metal surface comprising metal nitride residues and metal carbide residues to the process gas comprising an oxidizing agent in a process chamber having a plasma source power of 1 to 5000 W and a plasma bias power of 1 to 500 W.

18. The non-transitory computer readable medium of claim 15, wherein the method further comprises:
exposing the substrate comprising a dielectric surface and a metal surface comprising metal oxides residues to the process gas comprising a reducing agent in a process chamber having a temperature of 20 degrees Celsius to 400 degrees Celsius and a pressure of 1 mTorr to 500 mTorr.

19. The non-transitory computer readable medium of claim 15, wherein the method further comprises:
exposing the substrate comprising a dielectric surface and a metal surface comprising metal oxides residues to the process gas comprising a reducing agent in a process chamber having a plasma source power of 1 to 5000 W and a plasma bias power of 1 to 500 W.

20. The non-transitory computer readable medium of claim 15, wherein the process gas comprising an oxidizing agent comprises a mixture of oxygen and argon, or a mixture of oxygen and helium, and wherein the reducing agent is a mixture of hydrogen and argon, hydrogen and nitrogen or hydrogen and helium.
